(19) United States
(12) Patent Application Publication
(10) Pub. No.: US 2010/0255387 A1
(43) Pub. Date: Oct. 7, 2010

(54) PHOTO-ACTIVATION OF SOLID OXIDE FUEL CELLS AND GAS SEPARATION DEVICES

(75) Inventors: Shriram Ramanathan, Acton, MA (US); Annamalai Karthikeyan, Quincy, MA (US)

Correspondence Address: Elizabeth Eunjoo Kim;Rauschenbach Patent Law Group, LLP, 43 Hackensack Road, Chestnut Hill, MA, 02467-9998, US

(73) Assignee: PRESIDENT AND FELLOWS OF HARVARD COLLEGE, Cambridge, MA (US)

(21) Appl. No.: 12/521,572

(22) PCT Filed: Dec. 27, 2007
(86) PCT No.: PCT/US07/88952

§ 371 Date: Jun. 10, 2010

Related U.S. Application Data
(60) Provisional application No. 60/882,019, filed on Dec. 27, 2006.

(51) Int. Cl. H01M 8/10; C23C 16/44; H01M 8/04

(52) U.S. Cl. 429/408; 427/595

(57) ABSTRACT

In various aspects, provided are methods for: (a) improving oxygen incorporation in a solid oxide layer less than about 1000 nm thick; (b) extending the on-set of mixed conduction in a solid oxide layer less than about 1000 nm thick; (c) modulating the electrical conductivity of oxide ion conducting layer less than about 1000 nm thick; (d) decreasing the conductivity of an oxide ion conducting layer less than about 1000 nm thick; (e) improving the performance of a solid oxide fuel cell; and (f) improving the performance of a gas separation device. In various embodiments, the methods comprise exposing oxygen to light having one or more wavelengths in the range between about 100 nm to about 365 nm and contacting the layer with the oxygen so exposed. In various embodiments, the methods provide the potential for tailoring the surface catalytic activity of oxygen-ion and mixed conductors used in various solid-state devices.

### CROSS-REFERENCE TO RELATED APPLICATIONS

The present application claims the benefit of and priority to copending U.S. Provisional Patent Application No. 60/882,019, filed Dec. 27, 2006, the entire contents of which are herein incorporated by reference.

### BACKGROUND

Nanoscale oxide ceramics are important components in thin film energy conversion devices, gas separation devices, catalytic layers and multi-functional oxides. For example, yttria-doped zirconia (YDZ) is used in solid oxide fuel cells (SOFCs) and sensors.

Unfortunately, performance of one or more of the oxide ion conducting portions in many of these devices limits there commercial application. For example, traditional solid oxide fuel cells (SOFCs) must run at very high temperatures, 800-1100° C., to be effective. At such high temperatures, the choice of materials for the electrodes and structural components of the cell (membrane support, gas handling, sealants) is severely constrained, particularly in the reactive oxygen- and hydrogen-rich environments of a fuel cell.

### SUMMARY OF THE INVENTION

In various aspects, various embodiments of the present inventions provide methods for one or more of: (a) improving the oxygen incorporation in a solid oxide layer less than about 1000 nanometers (nm) thick; (b) extending the on-set of mixed conduction in a solid oxide layer less than about 1000 nm thick; (c) modulating the electrical conductivity of oxide ion conducting layer less than about 1000 nm thick; (d) decreasing the conductivity of an oxide ion conducting layer less than about 1000 nm thick; (e) improving the performance of a solid oxide fuel cell; and (f) improving the performance of a gas separation device. In various embodiments, the methods comprise exposing oxygen to light having one or more wavelengths in the range between about 100 nm to about 365 nm and contacting the layer with the oxygen so exposed. In various embodiments, the light has a power density within this range of wavelengths of greater than about one or more of: about 5 mW/cm², about 10 mW/cm², about 20 mW/cm², about 40 mW/cm², about 60 mW/cm², about 80 mW/cm², about 100 mW/cm², about 200 mW/cm², about 400 mW/cm², about 600 mW/cm², and/or about 1 W/cm².

As used herein the term “activated oxygen” refers to oxygen (O₂) that has been exposed to light having one or more wavelengths in the range between about 100 nm to about 365 nm.

Various embodiments of the present inventions can find practical application in improving the performance of various SOFCs, solid oxide electrolyzer cells (SOECs), gas separation membranes and similar electrochemical devices by accelerating gas-to-solid reaction kinetics by providing activated oxygen to such devices. The performance of these electrochemical devices often depends on oxygen ion transport within the material, determined by conductivity and/or diffusivity, for example, and with the ambient often determined by the surface diffusion and/or exchange rates of oxygen.

Various embodiments of the present inventions can find practical application in improving the performance of various dielectric materials such as, for example, gate dielectrics for transistors, thin film capacitors for memory storage, thin film capacitors for charge storage, etc. The performance of these devices can often benefit from a reduction in ionic conductivity that can be provided by various embodiments of the present inventions.

In various embodiments of the methods of the present invention can be applied, for example, to an oxide ion conducting electrolyte layer of a SOFC can increase the SOFC power density and/or, e.g., minimizing SOFC losses due to mass transport and activation. Applied, for example, to a gas separation device, various embodiments of the methods of the present invention can be used to increase flux.

In various embodiments, the methods of the present inventions provide an increase in oxygen incorporation, and/or decrease in vacancy concentration, of the material treated. For example, in various embodiments provided are methods for enhancing oxygen incorporation and the cathode/solid electrolyte interface of a SOFC. It is believed, without being held to theory, that in various embodiments an increase in oxygen incorporation, and/or decrease in vacancy concentration, occurs at the near surface layers of the material and that is subsequently transported to the bulk of the material.

In various embodiments, the present inventions provide methods for producing an abrupt and/or reversible modulation of electrical conductivity of oxide ion conducting layers having a thickness of less than about 1000 nanometers (nm).

As used herein, the term “oxide ion” refers to the ion O²⁻. Examples of oxide ion conducting materials include, but are not limited to, doped-fluorites and doped-perovskites. As used herein the term “oxide ion conducting layer” refers to a material capable of conducting oxide ions but is not limited to materials that only conduct oxide ions. For example, the term “oxide ion conducting layer” includes materials that conduct other ionic species, protons, electrons, or combinations thereof.

It is to be understood that although various embodiments of the methods of the present invention are discussed as being applied to “layers,” “membranes,” and “films” that the actual form factor of a oxide ion conducting structure having a thickness of less than about 10000 nm is not limited to being planar or substantially planar. Various embodiments of the methods of the present inventions can be applied to a wide variety of form factors including corrugated, curved, bent, cylindrical, etc.

It is to be understood that various embodiments of the methods of the present inventions can be applied to solid oxide layers having lateral dimensions substantially greater than the nanometer scale, such as for example on the order of microns, 10's of microns, 100's of microns, millimeters, centimeters and larger.

The methods of the present inventions can be applied to solid oxide layers less than about 1000 nm thick in a variety of devices and device elements. For example, in various embodiments, the photo-irradiation methods can be applied to oxide ion conducting materials as well as mixed conductors. Examples of devices and structure to which various embodiments of the methods can be applied, include, but are not limited to: (a) oxide ion conducting oxygen sensing membranes; (b) oxide ion conducting electrolytes in solid oxide fuel cells (SOFCs); (c) oxide ion conducting electrolytes in solid oxide electrolyzer cells (SOECs); (d) mixed conductor electrodes, e.g., in SOFCs; and (e) mixed conductor membrane for gas separation, e.g., separation of oxygen from gas mixtures and/or steam to generate hydrogen.

For example, in various aspects provided are methods for improving the operation of a solid oxide fuel cell having a solid oxide electrolyte layer less than about 1000 nm thick. In various embodiments the methods irradiate oxygen with light having one or more wavelengths in the range between about 100 nm to about 365 nm; and deliver the irradiated oxygen to the cathode side of a solid oxide fuel cell having a solid oxide electrolyte layer less than about 1000 nm thick in an amount sufficient to substantially maintain one or more of the power density and power output provided by the solid oxide fuel cell at a first operating temperature as compared to the corresponding power density and/or power output provided by the solid oxide fuel cell prior to delivery of the irradiated oxygen that is operated at a second operating temperature higher than the first operating temperature. In various embodiments, the step of delivering the irradiated oxygen to the cathode side comprises irradiating the cathode side of the solid oxide fuel cell with light having one or more wavelengths in the range between about 100 nm to about 365 nm. In various embodiments the first operating temperature is one or more of: (a) at least 100° C. less than the second operating temperature; (b) at least 150° C. less than the second operating temperature; (c) at least 200° C. less than the second operating temperature; (d) at least 250° C. less than the second operating temperature; (e) at least 300° C. less than the second operating temperature; and (f) at least 350° C. less than the second operating temperature.

For example, in various aspects provided are methods for improving the operation of a solid oxide fuel cell having a solid oxide electrolyte layer less than about 1000 nm thick. In various embodiments the methods irradiate oxygen with light having one or more wavelengths in the range between about 100 nm to about 365 nm and deliver the irradiated oxygen to the cathode side of a solid oxide fuel cell having a solid oxide electrolyte layer less than about 1000 nm thick in an amount sufficient to increase one or more of the power density and power output provided by the solid oxide fuel cell as compared to the corresponding power density and/or power output provided by the solid oxide fuel cell prior to delivery of the irradiated oxygen. In various embodiments, the step of delivering the irradiated oxygen to the cathode side comprises irradiating the cathode side of the solid oxide fuel cell with light having one or more wavelengths in the range between about 100 nm to about 365 nm.

### BRIEF DESCRIPTION OF THE DRAWINGS

The foregoing and other aspects, embodiments, objects, features and advantages of the present inventions can be more fully understood from the following description in conjunction with the accompanying drawings. In the drawings, like reference characters generally refer to like features and structural elements throughout the various Figures. The drawings are not necessarily to scale, emphasis instead being placed upon illustrating the principles of the present inventions, wherein.

FIG. 1 is a schematic illustration of the extension of the on-set of mixed ionic and electronic conduction in a gadolina doped ceria film by contact of activated oxygen with the film according to various embodiments of the present inventions where “activate sample” refers to gadolina doped ceria film contacted with activated oxygen, and “unactivated sample” referres to gadolina doped ceria film not so contacted.

FIG. 2 is a schematic illustration of an experimental setup used for electrical measurements on nanoscale YDZ films under photon irradiation in Example 1. The sample holder assembly was made of alumina and was installed at the hot zone. The photon irradiation sources were built at the top and were continuously air cooled.

FIGS. 3A-B are impedance plots of about 70 nm thick YDZ film samples in Example. FIG. 3A presents data for samples at 885° C. with and without UV irradiation for two cycles. FIG. 3B presents data for samples at 830° C. with and without green laser (532 nm) irradiation.

FIG. 4 depicts an Arrhenius plot of temperature dependence of conductivity for samples of various thicknesses of in Example 1 obtained from AC impedance measurements. In the figure, open symbols show conductivity in presence of photo illumination in accordance with various embodiments of the present inventions in air and the filled symbols show conductivity under normal conditions in air.

FIG. 5 presents a plot of normalized changes in dc conductivity obtained from galvanostatic measurements for YDZ films of two different thicknesses of Example 1. The Y70 data (open circles) is for a YDZ layer about 70 nm thick and the Y933 data (open squares) is for a layer about 933 nm thick. The changes in single crystal YSZ (sample YSC, filled squares) is also shown for reference.

### DETAILED DESCRIPTION OF VARIOUS EMBODIMENTS

Nanoscale materials can often behave differently than there bulk counterparts. For example, significant differences have been observed in the electrical properties such as, size-dependent conductivity of nanoscale fluorite-oxides (such as YDZ) compared to bulk counterparts. For example, it has been observed that enhancements in total conductivity in YDZ is not substrate specific and activation energy for relaxation process obtained from modulus spectroscopy is significantly higher than the migration energy obtained from ion conductivity measurements.

In the present application, various embodiments of methods for utilizing activated oxygen to modify, modulate, and/or improve the properties of oxide ion conducting and/or solid oxide layers are provided.

In various aspects, the present inventions provide methods for decreasing the electrical conductivity of an oxide ion conducting layer less than about 1000 nm thick. In general the methods comprise the steps of irradiating oxygen with light having one or more wavelengths in the range between about 100 nm to about 365 nm, and contacting the surface of the oxide ion conducting layer with the irradiated oxygen in a quantity sufficient to decrease the electrical conductivity of the oxide ion conducting layer.

In various embodiments, the methods contact the oxide ion conducting layer with the irradiated oxygen in a quantity sufficient to decrease the electrical conductivity of the oxide ion conducting layer by one or more of: greater than about 10%; greater than about 20%; greater than about 30%; greater than about 40%; and/or greater than about 50%. In various embodiments, the ability to decrease the electrical conductivity of an oxide ion conducting layer can be of use n in improving the performance of various dielectric materials such as, for example, gate dielectrics for transistors, thin film capacitors for memory devices, thin film capacitors for charge storage, etc.

In various aspects, the present inventions provide methods for reversibly modulating the electrical conductivity of an oxide ion conducting layer less than about 1000 nm thick. In general the methods comprise the steps of: (i) irradiating oxygen with light having one or more wavelengths in the range between about 100 nm to about 365 nm; (ii) contacting the surface of the oxide ion conducting layer with the irradiated oxygen in a quantity sufficient to change the electrically conductivity of the oxide ion conducting layer to a second electrical conductivity value different from the first electrical conductivity value; and (iii) restoring the electrically conductivity of the oxide ion conducting layer substantially to the first electrical conductivity value by ceasing to contact the a surface of the oxide ion conducting layer with the irradiated oxygen.

In various embodiments, the methods contact the oxide ion conducting layer with the irradiated oxygen in a quantity such that the second electrical conductivity value differs from the first electrical conductivity value by one or more of: greater than about 10%; greater than about 20%; greater than about 30%; greater than about 40%; and/or greater than about 50%. In various embodiments, the second electrical conductivity value is less than the first electrical conductivity value.

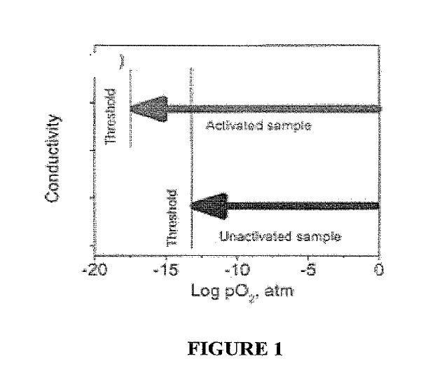

In aspects embodiments, methods of the present inventions can delay the onset of electronic conduction in a solid oxide layer, that is, e.g., onset does not occur until lower partial pressures of oxygen. For example, referring to FIG. 1, in various embodiments the methods of the present invention can be used to, e.g., retain the ionic conductivity domain of an oxide to lower operating partial pressures of oxygen. Mixed conduction (e.g., onset of electronic conduction) can be, e.g., a detrimental in the performance of a SOFC and such onset is typically of greatest concern on the anode side of SOFC given the reductive environment typically found there.

In various aspects, the present inventions provide methods for extending the on-set of mixed conduction in a solid oxide layer less than about 1000 nm thick. In general the methods comprise the steps of: irradiating oxygen with light having one or more wavelengths in the range between about 100 nm to about 365 nm; and contacting the surface of the mixed ionic and electronic conducting layer with the irradiated oxygen in a quantity sufficient to decrease the onset of electronic conduction (e.g., onset of mixed conduction for a nominally ionic conductor) to an oxygen partial pressure that is in the range between about half an order of magnitude to about five orders of magnitude lower than the oxygen partial pressure at which an equivalent level of electronic conduction occurs in the solid oxide layer prior to expose to the irradiated oxygen. In various embodiments, irradiated oxygen in a quantity sufficient to decrease the onset of electronic conduction, as compared to the oxygen partial pressure at which an equivalent level of electronic conduction occurs in the solid oxide layer prior to expose to the irradiated oxygen, by one or more of: (a) greater than about half an order of magnitude; (b) greater than about one order of magnitude; (c) greater than about two orders of magnitude; (d) greater than about three orders of magnitude; (e) greater than about four orders of magnitude; and (f) greater than about five orders of magnitude.

In various aspects, the present inventions provide methods for improving the oxygen incorporation in a solid oxide layer less than about 1000 nm thick. In general the methods comprise the steps of irradiating oxygen with light having one or more wavelengths in the range between about 100 nm to about 365 nm; and contacting the surface of the solid oxide layer with the irradiated oxygen.

In various aspects, the present inventions provide methods for improving the operation of a one or more of a solid oxide fuel cell, solid oxide electrolyzing cell, and/or gas separation device having a solid oxide electrolyte layer less than about 1000 nm thick. In general the methods comprise the steps of irradiating oxygen with light having one or more wavelengths in the range between about 100 nm to about 365 nm; and delivering the irradiated oxygen to the cathode side of the solid oxide fuel cell having a solid oxide electrolyte layer less than about 1000 nm thick in an amount sufficient to improve the power performance of the solid oxide fuel cell. In various embodiments, the methods also comprise irradiating the cathode and/or solid oxide electrolyte layer with light having one or more wavelengths in the range between about 100 nm to about 365 nm.

In various embodiments, the methods comprise irradiating the cathode and/or solid oxide electrolyte layer with light having one or more wavelengths in the range between about 100 nm to about 365 nm and a power density within this range of wavelengths of greater than about one or more of: about 5 mW/cm², about 10 mW/cm², about 20 mW/cm², about 40 mW/cm², about 60 mW/cm², about 80 mW/cm², about 100 mW/cm², about 200 mW/cm², about 400 mW/cm², about 600 mW/cm², and/or about 1 W/cm². In various embodiments, the light source comprises an incoherent source, such as, for example, a UV lamp, e.g., a mercury lamp. In various embodiments, the light source comprises an coherent source, such as, for example, a laser.

In various embodiments, the light source comprises concentrated solar radiation. In various embodiments, the methods comprise concentrating solar radiation onto the cathode side of a SOFC to improve SOFC performance. For example, in various embodiments, the methods comprise concentrating the solar radiation onto the air stream at the cathode side and/or at the cathode-electrolyte interface region. In various embodiments, the methods comprise concentrating nominal incident solar radiation by a factor of one or more of: (a) by greater than about 1.5 times; (b) by greater than about 2 times; (c) by greater than about 3 times; and (d) by greater than about 10 times.

In various embodiments, the methods increase one or more of the power density and/or power output at a given operating temperature as compared to the corresponding power performance parameter of the SOFC at the given temperature prior to delivery of the irradiated oxygen. In various embodiments, the methods increase one or more of the power density and/or power output at a given operating temperature as compared to the corresponding power performance parameter of the SOFC at the given temperature prior to delivery of the irradiated oxygen and irradiation of the cathode of the SOFC with light having one or more wavelengths in the range between about 100 nm to about 365 nm.

In various embodiments, the methods decrease the temperature at which one or more of a given power density and/or power output can be obtained as compared to the corresponding power performance parameter of the SOFC prior to delivery of the irradiated oxygen. In various embodiments, the decrease in operating temperature is greater than one or more of: (a) about 100° C.; (b) about 150° C.; (c) about 200° C.; (d) about 300° C.; (e) about 350° C.; and (f) about 400° C.

In various embodiments, the methods decrease the temperature at which one or more of a given power density and/or power output can be obtained as compared to the corresponding power performance parameter of the SOFC prior to delivery of the irradiated oxygen and irradiation of the cathode of the SOFC with light having one or more wavelengths in the range between about 100 nm to about 365 nm. In various embodiments, the decrease in operating temperature is greater than one or more of: (a) about 100° C.; (b) about 150° C.; (c) about 200° C.; (d) about 300° C.; (e) about 350° C.; and (f) about 400° C.

In various embodiments of the various aspects of the present inventions, modification of a layers properties by activated oxygen can be used to modify, modulate and/or control the surface catalytic activity in various devices based on oxide nanostructures. In various embodiments, the methods provide the potential for tailoring the surface catalytic activity of oxygen-ion and mixed conductors used in various solid-state devices such as, for example solid oxide fuel cell and gas separation membranes that use mixed conductors.

In various embodiments of the various aspects of the present inventions, contacting the various surfaces with activated oxygen (e.g., oxygen irradiated with light having one or more wavelengths in the range between about 100 nm to about 365 nm) comprises irradiating the surface to be contacted with activated oxygen with light having one or more wavelengths in the range between about 100 nm to about 365 nm. In various embodiments, irradiation of the surface with light comprise irradiating a layer over the surface that is to be contacted with the activated oxygen.

### Delivery of Activated Oxygen & Light

The various embodiments of the present invention do not require that the activated oxygen be formed immediate adjacent the surface to be contacted. For example, in various embodiments, oxygen is irradiated with UV light up-stream (for example in a gas flow line, chamber, etc.) and the activated oxygen delivered to the surface. In various embodiments, the oxygen activated is that in the chamber of portion of a device containing the surface to be contacted. In various embodiments, the chamber of portion of a device containing the surface to be contacted is a substantially closed chamber.

In various embodiments, the pressure of activated oxygen is in the range between about 1×10⁻¹° to about 1000 torr. In various embodiments, the pressure of activated oxygen is one or more of: (a) in the range between about 400 torr to about 1000 torr; (b) in the range between about 100 to about 400 torr; and (c) in the range between about 1 torr to about 100 torr.

In various embodiments of the various aspects of the present inventions, contacting the various surfaces with activated oxygen (e.g., oxygen irradiated with light having one or more wavelengths in the range between about 100 nm to about 365 nm) comprises irradiating the surface to be contacted with activated oxygen with light having one or more wavelengths in the range between about 100 nm to about 365 nm.

In various embodiments, irradiation of the surface with light comprise irradiating a layer over the surface that is to be contacted with the activated oxygen. For example, in various embodiments the surface to be contacted with activated oxygen comprises the electrolyte of a SOFC, e.g., contact by transport of activated oxygen through a cathode layer, an anode layer, or both over the electrolyte layer. In various embodiments, irradiating the electrolyte layer with light can be accomplished by irradiating the overlying cathode layer, anode layer, or both with light having one or more wavelengths in the range between about 100 nm to about 365 nm. In various embodiments, the methods comprise concentrating the solar radiation onto the air stream at the cathode side and/or at the cathode-electrolyte interface region

In various embodiments of the various aspects of the present inventions comprising irradiation of a layer with light having one or more wavelengths in the range between about 100 nm to about 365 nm, various embodiments of the methods comprise irradiating with light that has a power density within this range of wavelengths of greater than about one or more of: about 5 mW/cm², about 10 mW/cm², about 20 mW/cm², about 40 mW/cm², about 60 mW/cm², about 80 mW/cm², about 100 mW/cm², about 200 mW/cm², about 400 mW/cm², about 600 mW/cm², and/or about 1 W/cm². In various embodiments, the light source comprises an incoherent source, such as, for example, a UV lamp, e.g., a mercury lamp. In various embodiments, the light source comprises an coherent source, such as, for example, a laser.

In various embodiments, the light source comprises concentrated solar radiation. For example, in various embodiments, the methods comprise concentrating solar radiation onto the cathode side of a SOFC to improve SOFC performance. In various embodiments, the methods comprise concentrating the solar radiation onto the air stream at the cathode side and/or at the cathode-electrolyte interface region of a SOFC, SOEC and/or gas separation device.

### Layers & Devices

The methods of the present inventions are applicable to films having a thickness of less than about 1000 nm. In various embodiments, the film layer is less than about one or more of: (a) 500 nm thick; (a) 200 nm thick; (a) 100 nm thick; (b) 75 nm thick; (c) 50 nm thick; (d) 25 nm thick; and (e) 10 nm thick.

It is to be understood that various embodiments of the methods of the present inventions can be applied to solid oxide layers having lateral dimensions substantially greater than the nanometer scale, such as for example on the order of microns, 10's of microns, 100's of microns, millimeters, centimeters and larger.

The methods of the present inventions can be applied to solid oxide layers less than about 1000 nm thick in a variety of devices and device elements. For example, in various embodiments, the photo-irradiation methods can be applied to oxide ion conducting materials as well as mixed conductors. Examples of devices and structure to which various embodiments of the methods can be applied, include, but are not limited to: (a) oxide ion conducting oxygen sensing membranes; (b) oxide ion conducting electrolytes in solid oxide fuel cells (SOFCs); (c) oxide ion conducting electrolytes in solid oxide electrolyzer cells (SOECs); (d) mixed conductor electrodes, e.g., in SOFCs; and (e) mixed conductor membrane for gas separation, e.g., separation of oxygen from gas mixtures and/or steam to generate hydrogen.

In various embodiments, the methods of the present inventions can be applied to a variety of oxide ion conducting solid oxide electrolyte layers including, but not limited to, a polycrystalline ceramic comprising one or more stabilized zirconia, partially stabilized zirconia, stabilized hafnia, partially stabilized hafnia, mixtures of zirconia and hafnia, ceria with zirconia, bismuth with zirconia, gadolinium, germanium, doped partially stabilized zirconia, doped stabilized zirconia, and mixtures thereof. Examples of dopants include, but are not limited to, one or more of the oxides of Y, Ce, Ca, Mg, Sc, Nd, Sm, Eu, Gd, Th, Dy, Ho, Er, Tm, Yb, Lu, In, Ti, Sn, Nb, Ta, Mo, and W and mixtures thereof. For example, in various embodiments, the solid oxide electrolyte comprises a polycrystalline ceramic comprising one or more of yttria-doped bismuth oxide (YDB), gadolinia-doped ceria (GDC), and yttria-stabilized zirconia (YSZ).

In various embodiments, the solid oxide electrolyte can comprise two or more layers of differing solid oxide materials. In various embodiments, the solid oxide comprises a first inner solid oxide electrolyte layer disposed between a first outer solid oxide electrolyte layer and a second outer solid oxide electrolyte layer, where the material of the first inner solid oxide electrolyte layer is different from that of at least one of the first and second outer solid oxide electrolyte layers. In various embodiments, the first inner solid oxide electrolyte layer is both an ionic and electronic conductor, and the first and second outer solid oxide electrolyte layers are substantially only ionic conductors.

In various embodiments, the methods of the present invention can be applied to mixed ionic and electronic conducting (MIEC) electrode layers. In various embodiments such MIEC layers can comprise a double doped cerium oxide, zirconium oxide, and/or lanthanum gallium oxide. In various embodiments, the layers comprise (a) a first dopant; (b) a second dopant; and (c) a ceramic oxide; wherein the first dopant is one of more of Y₂O₃, Sm₂O₃, Sc₂O₃, Gd₂O₃, SrO, MgO, and MnO; the second dopant is one or more metal oxides BₘOₙ, where B represents V, Nb, Ti, Mn, Cr or Fe; and the ceramic oxide is one or more of ZrO₂, CeO₂, and LaGaO₃.

In various embodiments, the methods of the present invention can be applied to graded MIEC layers, sometimes referred to by the abbreviation GMIC for succinctness. In various embodiments, a GMIC comprises two or more layers of nano-membrane MIEC layers, where each MIEC layer comprises (a) a first dopant; (b) a second dopant; and (c) a ceramic oxide; wherein the first dopant is one of more of Y₂O₃, Sm₂O₃, Sc₂O₃, Gd₂O₃, SrO, MgO, and MnO; the second dopant is one or more metal oxides BₘOₙ, where B represents V, Nb, Ti, Mn, Cr or Fe; and the ceramic oxide is one or more of ZrO₂, CeO₂, and LaGaO₃.

It is to be understood that although various embodiments of the methods of the present invention are discussed as being applied to “layers,” “membranes,” and “films” that the actual form factor of a oxide ion conducting structure having a thickness of less than about 10000 nm is not limited to being planar or substantially planar. Various embodiments of the methods of the present inventions can be applied to a wide variety of form factors including corrugated, curved, bent, cylindrical, etc.

The methods of the present inventions can be applied to SOFC, SOEC, sensors and gas separation devices comprised of a variety of different anode and cathode materials. For example, anode materials including, but not limited to, Ni, zirconia, Y-doped zirconia, Cu, ceria, Gd-doped ceria, alio-valently doped oxide ceramics, and combinations thereof. For example, cathode materials including, but not limited to, Pt, Au, Ta, Ru, Ir, Cu, La, Sr, Fe, LaMnO₃, SrMnO₃, (La₁₋ₓSrₓMnO₃), La₁₋ₓSrₓCO_{1-y}Fe_{y}O₃, and combinations thereof.

### Photon Source

A variety of photon sources, light sources, can be used to perform UV irradiation in the practice of the methods of the present invention. In various embodiments, the methods comprise irradiating oxygen with light having one or more wavelengths in the range between about 100 nm to about 365 nm wherein the light has a power density within this range of wavelengths of greater than about one or more of: about 5 mW/cm², about 10 mW/cm², about 20 mW/cm², about 40 mW/cm², about 60 mW/cm², about 80 mW/cm², about 100 mW/cm², about 200 mW/cm², about 400 mW/cm², about 600 mW/cm², and/or about 1 W/cm². In various embodiments, the light source comprises an incoherent source, such as, for example, a UV lamp, e.g., a mercury lamp. In various embodiments, the light source comprises an coherent source, such as, for example, a laser.

In various embodiments, the light source comprises concentrated solar radiation. For example, in various embodiments, the methods comprise concentrating solar radiation onto the air stream at the cathode side and/or at the cathode-electrolyte interface region of, e.g., a SOFC, SOEC, and/or gas separation device. A wide variety of solar concentrators are usable with various embodiments of the present inventions including, but not limited to, those employing lenses and those employing mirrors. In various embodiments, the methods comprise concentrating nominal incident solar radiation by a factor of one or more of: (a) by greater than about 1.5 times; (b) by greater than about 2 times; (c) by greater than about 3 times; and (d) by greater than about 10 times.

### EXAMPLES

The present examples provide experimental data on the use of UV irradiation methods on yttria-doped zirconia (YDZ) films according to various embodiments of the present inventions.

Y-doped zirconia is a high permittivity dielectric with a wide band gap and the presence of oxygen non-stoichiometry and defects in YDZ are expected to introduce localized states. Photoluminescence (PL) studies of stabilized zirconia indicate that inter-band absorption occurs around 4-5 eV depending on temperature. The proposed band diagrams also predict states due to defects around 2-3 eV that correspond to wavelengths of about 500 nm.

It is to be understood that although the following examples often discuss the methods in terms of irradiation of a sample, irradiation of the oxygen that is delivered to the layer is sufficient and that the layer itself need not be irradiated.

In the present examples the following materials and methods were used unless otherwise noted.

### Materials and Methods

In the following examples, 9.5% yttria-doped zirconia (YDZ) films of different thickness were deposited on single crystal sapphire, Al₂O₃, (0001) (from MTI Corporation) by various methods. YDZ films with thickness in the range between about 30 nm to about 1000 nm were prepared by the methods as shown in Table 1. Film thicknesses were measured using Rutherford backscattering and low angle x-ray scattering.

TABLE 1

| Sample ID | Film Thickness | | Synthesis method |
|---|---|---|---|
| Y70 | 70 | nm | E-beam |
| Y933 | 933 | nm | E-beam |
| Y33 | 33 | nm | RF-sputtering |
| YSC | 500 | μm | |

Films were also formed by RF sputtering carried out in argon at a background pressure of 5 mTorr using an 8% YSZ target for comparison. In addition, a single crystal YSZ (labeled as YSC in Table 1) measuring about 10 mm×about 10 mm and having a thickness of about 0.5 mm was used as a reference sample to represent a model bulk system. A mercury vapor UV lamp with a primary wavelength of 254 nm and an ancillary major wavelength at 185 nm was used as the UV photon source. The lamp produced a total UV power density of about 50 mW/cm².

In some examples comparison was also made to YDZ films grown on MgO (100). Single crystal MgO (100) (purchased from MTI Corporation) were used as substrates for depositing yttria-doped zirconia films of varying thickness. The film deposition was carried out by electron beam evaporation with the substrate at room temperature at an estimated deposition rate of 0.5 Angstroms/second (Å/s). Yttria stabilized zirconia (YSZ) (9.5 mol % yttria) pieces were used as the source material. The MgO substrate was first cleaned in acetone, methanol, and subsequently with de-ionized water and then heat treated to 600° C. in situ in the electron beam chamber for 30 min. Film thicknesses were measured using Rutherford backscattering and low angle x-ray scattering.

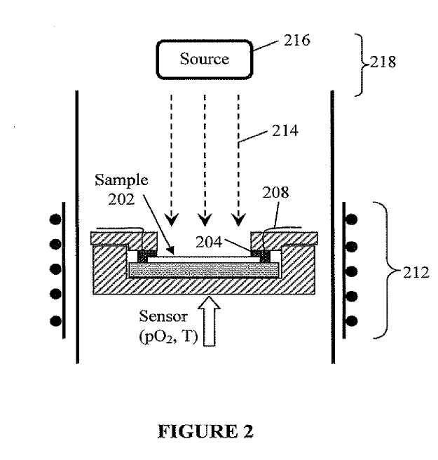

The electrical conductivity measurements were carried out using a high temperature set-up comprising of a machined alumina sample holder that was built into a furnace and the electrical leads were made of pure platinum, schematically illustrated in FIG. 2, showing, among other things, the sample 202, alumina sample holder 204, electrodes and platinum leads 208. Platinum paste was used as the electrode contact with the samples in a two-probe configuration and heat treated to 900° C. for 2 hours for good contact formation. Four platinum leads were attached to the electrodes for independent current and voltage measurements.

Referring to FIG. 2, the samples 202 were held horizontally on an alumina platen 204 with the film surface facing up and clear through an opening in the alumina holder. This assembly was held in the hot zone of the furnace 212 and UV light 214 from the mercury lamp 216 was shone from the colder top part 218 of the apparatus. Oxygen flow was into and out of the plane of the image in FIG. 2.

### Example 1

### Comparison of UV and 532 nm Irradiation

AC impedance measurements were carried out using a Solartron electrochemical system in the frequency range of 1 Hz-300 kHz and in the temperature range of 950-1160° C. in air with and without the presence of UV radiation after sufficient equilibration at each temperature. A similar setup was used to perform measurements using a coherent 532 nm wavelength light source. Substantially identical experiments were performed on bare substrates as well for comparison.

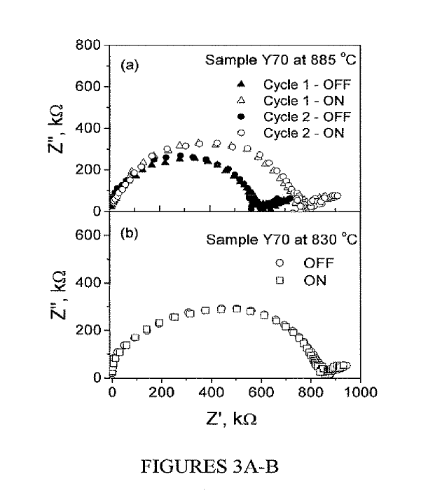

Referring to FIG. 3A, sample AC impedance spectra of the samples having about a 70 nm thick YZD layer (Y70) at 885° C. recorded with UV radiation (open circles and triangles) and without the UV radiation (filled circles and triangles) are shown. The plots show one semicircular arc corresponding to ionic conduction in the film and some low frequency features due to electrode processes. In the presence of UV radiation (open circles and triangles); however, the resistance of the sample is significantly higher. The results were found to be reproducible substantially without any hysteretic effects over several on-off cycles. The low frequency spike indicates the presence of phase elements due to charge transfer processes. When exposed to UV radiation, no noticeable changes in the shape and slope of these features were seen until about 0.01 Hz.

Referring to FIG. 3B, similar measurements are shown for irradiation with (square symbols) and without (circular symbols) irradiation by about 532 nm light with the samples at about 830° C. The sample resistance was observed to remain unperturbed when exposed to about 532 nm photons from a laser. The energy of these photons was about 2.3 eV; close to the predicted transition levels in YSZ; however, this radiation was not observed to change the electrical conductivity of the films.

### Example 2

### Temperature Dependence of Conductivity With and Without Irradiation

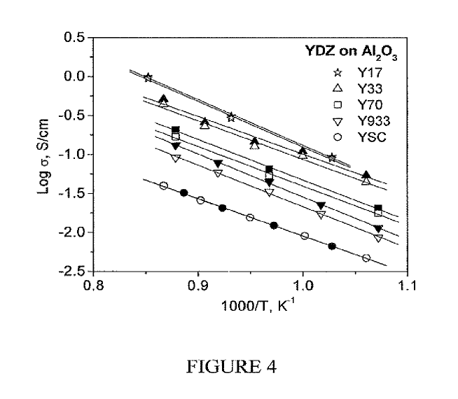

Referring to FIG. 4, the temperature dependence of the conductivity of the films with (filled symbols) and without (open symbols) UV radiation in air are shown in the form of Arrhenius plots for various film thicknesses. The total conductivity is observed to decrease when the samples are irradiated with UV. The activation energies for ion transport measured for the samples were about 1.0 eV and remain unchanged under UV irradiation. UV induced conductivity changes on similar films grown on MgO (100) were also studied using a 4-probe van der Pauw method as a function of temperature. A similar order of decrease in conductivity was observed in YDZ films grown on MgO (100).

It is believed, without being held to theory, that the nanometer scale thickness of the YDZ films, the UV light has influence though the sample thickness (e.g., both surface and bulk influence). To explore these beliefs, a single crystal YSZ sample about 0.5 mm thick thick, representing a bulk material, shows very low (less than 1%) decrease in conductivity when measured under UV illumination as compared to no illumination. Systematic studies performed on bare substrates also showed negligible variation in conductivity under UV radiation. It is believed, without being held to theory, that this indicates that the change in conductivity is primarily caused by modification in surface and near-surface layers.

Systematic conductivity studies on YDZ samples enclosed in a controlled atmosphere chamber with a fused silica optical window that is transparent in the UV regime were also performed. The reduction in conductivity in these experiments for the samples with a YDZ thickness of less than about 1000 nm was much higher than in the case of sample exposed to UV radiation in an open setup with flowing oxygen. For example, the reduction in conductivity was observed to be about 42% in the enclosed set up for a YDZ film with a thickness of about 20 nm, compared to about 17% that was measured using an open flow set up, e.g., as schematically shown in FIG. 2, for a sample film of substantially the same material and thickness.

### Example 3

### Further Investigation of the Process

UV radiation in the wavelength range of 180-300 nm is known to produce ozone by forming atomic oxygen (O₂+hv→20; O₂+O→O₃). It is believed, without being held to theory, that such activated oxygen can alter the thermochemical equilibrium at the near surface layers of a YDZ film. If such a surface modification leads to a net decrease in oxygen vacancies, reduction in conductivity would result. This process, however, requires two electrons, e.g., V_{O}^{••}+2e⁻+O→O_{O}^{x}.

It is also believed, without being held to theory, that excited electrons that are available at the near surface layers could participate in the surface oxygen incorporation process. t is also believed, without being held to theory, that electrons could be trapped by positively charged oxygen vacancies and form color centers; resulting in the reduction of effective concentration of oxygen vacancies that participate in electrical conduction.

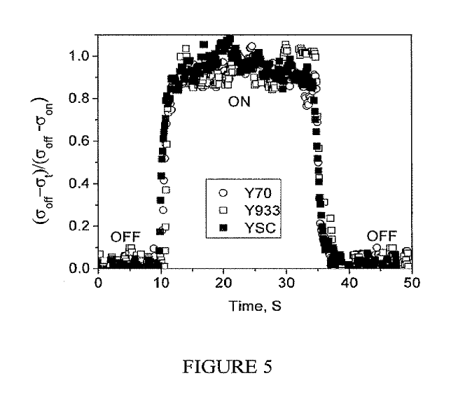

Referring to FIG. 5, electrical conductivity transients were studied by galvanostatic measurements (at intervals of 0.1 sec) in both nanoscale (less than about 1000 nm thick films) and bulk samples. A constant low dc current was passed through the sample and after sufficient stabilization; the UV source was switched on for 25 seconds and then shut off The relative changes in DC conductivity obtained by galvanostatic measurements are shown in FIG. 5 where the region with the designation “ON” refers to measurements with UV irradiation, and the region with the designation “OFF” refers to measurements without UV irradiation. The UV-activated changes were found to be similar in all samples independent of film thickness. It is believed, without being held to theory, that this indicates that oxygen incorporation and removal under the influence of UV radiation are near-surface processes and photo-activation enables rapid conductivity changes.

All literature and similar material cited in this application, including, patents, patent applications, articles, books, treatises, dissertations and web pages, regardless of the format of such literature and similar materials, are expressly incorporated by reference in their entirety. In the event that one or more of the incorporated literature and similar materials differs from or contradicts this application, including defined terms, term usage, described techniques, or the like, this application controls.

The section headings used herein are for organizational purposes only and are not to be construed as limiting the subject matter described in any way.

While the present inventions have been described in conjunction with various embodiments and examples, it is not intended that the present inventions be limited to such embodiments or examples. On the contrary, the present inventions encompass various alternatives, modifications, and equivalents, as will be appreciated by those of skill in the art. Accordingly, the descriptions, methods and diagrams of should not be read as limited to the described order of elements unless stated to that effect.

Although this disclosure has described and illustrated certain preferred embodiments of the invention, it is to be understood that the invention is not restricted to those particular embodiments. Rather, the invention includes all embodiments which are functional or mechanical equivalence of the specific embodiments and features that have been described and illustrated.

The claims should not be read as limited to the described order or elements unless stated to that effect. It should be understood that various changes in form and detail may be made without departing from the scope of the appended claims. Therefore, all embodiments that come within the scope and spirit of the following claims and equivalents thereto are claimed.

What is claimed is:

1. A method for decreasing the electrical conductivity of an oxide ion conducting layer less than about 1000 nm thick, comprising the steps of:
providing a substrate having an oxide ion conducting layer less than about 1000 nm thick;
irradiating oxygen with light having one or more wavelengths in the range between about 100 nm to about 365 nm; and
contacting a surface of the oxide ion conducting layer with the irradiated oxygen in a quantity sufficient to decrease the electrical conductivity of the oxide ion conducting layer.

2. The method of claim 1, wherein the step of irradiating oxygen with light comprises irradiating oxygen with light having power density greater than about 10 mW/cm².

3. The method of claim 2, wherein the step of irradiating oxygen with light comprises irradiating oxygen with light having power density greater than about 40 mW/cm².

4. The method of claim 1, wherein the step contacting a surface of the oxide ion conducting layer with the irradiated oxygen comprises contacting the surface with a quantity sufficient to decrease the electrical conductivity of the oxide ion conducting layer by greater than about 10%.

5. The method of claim 4, wherein the step contacting a surface of the oxide ion conducting layer with the irradiated oxygen comprises contacting the surface with a quantity sufficient to decrease the electrical conductivity of the oxide ion conducting layer by greater than about 20%.

6. The method of claim 5, wherein the step contacting a surface of the oxide ion conducting layer with the irradiated oxygen comprises contacting the surface with a quantity sufficient to decrease the electrical conductivity of the oxide ion conducting layer by greater than about 40%.

7. The method of claim 1, wherein the method comprises heating the oxide ion conducting layer such that when the irradiated oxygen contacts the surface of the oxide ion conducting layer, the surface has a temperature greater than about 400° C.

8. The method of claim 7, wherein the method comprises heating the oxide ion conducting layer such that when the irradiated oxygen contacts the surface of the oxide ion conducting layer, the surface has a temperature greater than about 600° C.

9. The method of claim 8, wherein the method comprises heating the oxide ion conducting layer such that when the irradiated oxygen contacts the surface of the oxide ion conducting layer, the surface has a temperature greater than about 800° C.

10. The method of claim 1, wherein the step of providing a substrate having an oxide ion conducting layer comprises providing an oxide ion conducting layer that comprises a polycrystalline ceramic comprising one or more of stabilized zirconia, partially stabilized zirconia, stabilized hafnia, partially stabilized hafnia, mixtures of zirconia and hafnia, ceria with zirconia, bismuth with zirconia, gadolinium, germanium, and mixtures thereof.

11. The method of claim 1, wherein the step of providing a substrate having an oxide ion conducting layer comprises providing an oxide ion conducting layer that comprises a polycrystalline ceramic comprising one or more of yttria-doped bismuth oxide (YDB), gadolinia-doped ceria (GDC), and yttria-stabilized zirconia (YSZ).

12. The method of claim 1, wherein the step of providing a substrate having an oxide ion conducting layer comprises providing an oxide ion conducting layer less than about 100 nm thick.

13. The method of claim 1, wherein the step of contacting a surface of the oxide ion conducting layer with the irradiated oxygen comprises irradiating the oxide ion conducting layer with light having one or more wavelengths in the range between about 100 nm to about 365 nm.

14. The method of claim 13, wherein irradiating the oxide ion conducting layer with light comprises irradiating the oxide ion conducting layer with light having power density greater than about 10 mW/cm².

15. A method for reversibly modulating the electrical conductivity of an oxide ion conducting layer less than about 1000 nm thick, comprising the steps of:
providing a substrate having an oxide ion conducting layer less than about 1000 nm thick and having a first electrical conductivity value;
irradiating oxygen with light having one or more wavelengths in the range between about 100 nm to about 365 nm;
contacting a surface of the oxide ion conducting layer with the irradiated oxygen in a quantity sufficient to change the electrically conductivity of the oxide ion conducting layer to a second electrical conductivity value different from the first electrical conductivity value; and
ceasing to contact the a surface of the oxide ion conducting layer with the irradiated oxygen thereby restoring the electrically conductivity of the oxide ion conducting layer substantially to the first electrical conductivity value.

16. The method of claim 15, wherein the step of irradiating oxygen with light comprises irradiating oxygen with light having power density greater than about 10 mW/cm².

17. The method of claim 16, wherein the step of irradiating oxygen with light comprises irradiating oxygen with light having power density greater than about 40 mW/cm².

18. The method of claim 15, wherein the second electrical conductivity value differs from the first electrical conductivity value by greater than about 10%.

19. The method of claim 18, wherein the second electrical conductivity value differs from the first electrical conductivity value by greater than about 20%.

20. The method of claim 19, wherein the second electrical conductivity value differs from the first electrical conductivity value by greater than about 40%.

21. The method of claim 15, wherein the method comprises heating the oxide ion conducting layer such that when the irradiated oxygen contacts the surface of the oxide ion conducting layer, the surface has a temperature greater than about 400° C.

22. The method of claim 21, wherein the method comprises heating the oxide ion conducting layer such that when the irradiated oxygen contacts the surface of the oxide ion conducting layer, the surface has a temperature greater than about 600° C.

23. The method of claim 22, wherein the method comprises heating the oxide ion conducting layer such that when the irradiated oxygen contacts the surface of the oxide ion conducting layer, the surface has a temperature greater than about 800° C.

24. The method of claim 15, wherein the step of contacting a surface of the oxide ion conducting layer with the irradiated oxygen comprises irradiating the oxide ion conducting layer with light having one or more wavelengths in the range between about 100 nm to about 365 nm.

25. The method of claim 24, wherein irradiating the oxide ion conducting layer with light comprises irradiating the oxide ion conducting layer with light having power density greater than about 10 mW/cm².

26. A method for extending the on-set of mixed conduction in an ionic conducting layer less than about 1000 nm thick, comprising the steps of:
providing a substrate having an ionic conducting layer less than about 1000 nm thick;
irradiating oxygen with light having one or more wavelengths in the range between about 100 nm to about 365 nm; and
contacting a surface of the ionic conducting layer with the irradiated oxygen in a quantity sufficient to lower the onset of electronic conduction to an oxygen partial pressure by more than about half an order of magnitude lower than the oxygen partial pressure at which an equivalent level of electronic conduction occurs in the ionic conducting layer prior to expose to the irradiated oxygen.

27. The method of claim 26, wherein the step contacting a surface of the ionic conducting layer with the irradiated oxygen comprises contacting the surface with a quantity sufficient to lower the onset of electronic conduction to an oxygen partial pressure by more than about one order of magnitude lower than the oxygen partial pressure at which an equivalent level of electronic conduction occurs in the ionic conducting layer prior to expose to the irradiated oxygen.

28. The method of claim 27, wherein the step contacting a surface of the ionic conducting layer with the irradiated oxygen comprises contacting the surface with a quantity sufficient to lower the onset of electronic conduction to an oxygen partial pressure by more than about two orders of magnitude lower than the oxygen partial pressure at which an equivalent level of electronic conduction occurs in the ionic conducting layer prior to expose to the irradiated oxygen.

29. The method of claim 28, wherein the step contacting a surface of the ionic conducting layer with the irradiated oxygen comprises contacting the surface with a quantity sufficient to lower the onset of electronic conduction to an oxygen partial pressure by more than about four orders of magnitude lower than the oxygen partial pressure at which an equivalent level of electronic conduction occurs in the ionic conducting layer prior to expose to the irradiated oxygen.

30. The method of claim 26, wherein the step of irradiating oxygen with light comprises irradiating oxygen with light having power density greater than about 10 mW/cm².

31. The method of claim 2, wherein the step of irradiating oxygen with light comprises irradiating oxygen with light having power density greater than about 40 mW/cm².

32. The method of claim 26, wherein the method comprises heating the ionic conducting layer such that when the irradiated oxygen contacts the surface of the ionic conducting layer, the surface has a temperature greater than about 400° C.

33. The method of claim 32, wherein the method comprises heating the ionic conducting layer such that when the irradiated oxygen contacts the surface of the ionic conducting layer, the surface has a temperature greater than about 600° C.

34. The method of claim 33, wherein the method comprises heating the ionic conducting layer such that when the irradiated oxygen contacts the surface of the ionic conducting layer, the surface has a temperature greater than about 800° C.

35. The method of claim 26, wherein the step of providing a substrate having an ionic conducting layer comprises providing an ionic conducting layer that comprises a polycrystalline ceramic comprising one or more of yttria-doped bismuth oxide (YDB), gadolinia-doped ceria (GDC), and yttria-stabilized zirconia (YSZ).

36. The method of claim 26, wherein the step of providing a substrate having an ionic conducting layer comprises providing an ionic conducting layer less than about 100 nm thick.

37. The method of claim 26, wherein the step of contacting a surface of the ionic conducting layer with the irradiated oxygen comprises irradiating the ionic conducting layer with light having one or more wavelengths in the range between about 100 nm to about 365 nm.

38. The method of claim 37, wherein irradiating the ionic conducting layer with light comprises irradiating the ionic conducting layer with light having power density greater than about 10 mW/cm².

39. A method for improving the oxygen incorporation in a solid oxide layer less than about 1000 nm thick, comprising the steps of:
providing a substrate having a solid oxide layer less than about 1000 nm thick;
irradiating oxygen with light having one or more wavelengths in the range between about 100 nm to about 365 nm; and
contacting a surface of the solid oxide layer with the irradiated oxygen.

40. The method of claim 39, wherein the step of irradiating oxygen with light comprises irradiating oxygen with light having power density greater than about 10 mW/cm².

41. The method of claim 40, wherein the step of irradiating oxygen with light comprises irradiating oxygen with light having power density greater than about 40 mW/cm².

42. The method of claim 39, wherein the method comprises heating the solid oxide layer such that when the irradiated oxygen contacts the surface of the solid oxide layer, the layer has a temperature greater than about 400° C.

43. The method of claim 42, wherein the method comprises heating the solid oxide layer such that when the irradiated oxygen contacts the surface of the solid oxide layer, the layer has a temperature greater than about 600° C.

44. The method of claim 43, wherein the method comprises heating the solid oxide layer such that when the irradiated oxygen contacts the surface of the solid oxide layer, the layer has a temperature greater than about 800° C.

45. The method of claim 39, wherein the step of providing 4 substrate having a solid oxide layer comprises providing a solid oxide layer that comprises a polycrystalline ceramic comprising one or more of stabilized zirconia, partially stabilized zirconia, stabilized hafnia, partially stabilized hafnia, mixtures of zirconia and hafnia, eerie with zirconia, bismuth with zirconia, gadolinium, germanium, and mixtures thereof.

46. The method of claim 39, wherein the step of providing a substrate having a solid oxide layer comprises providing a solid oxide layer that comprises a polycrystalline ceramic comprising one or more of yttria-doped bismuth oxide (YDB), gadolinia-doped ceria (GDC), and yttria-stabilized zirconia (YSZ).

47. The method of claim 39, wherein the step of providing a substrate having a solid oxide layer comprises providing a solid oxide layer less than about 100 nm thick.

48. The method of claim 39, wherein the step of contacting a surface of the solid oxide layer with the irradiated oxygen comprises irradiating the solid oxide layer with light having one or more wavelengths in the range between about 100 nm to about 365 nm.

49. The method of claim 48, wherein irradiating the solid oxide layer with light comprises irradiating the solid oxide layer with light having power density greater than about 10 mW/cm².

50. A method for improving the operation of a solid oxide fuel cell having a solid oxide electrolyte layer less than about 1000 nm thick, comprising the steps of:
irradiating oxygen with light having one or more wavelengths in the range between about 100 nm to about 365 run; and
delivering the irradiated oxygen to the cathode side of a solid oxide fuel cell having a solid oxide electrolyte layer less than about 1000 nm thick in an amount sufficient to substantially maintain one or more of the power density and power output provided by the solid oxide fuel cell at a first operating temperature as compared to the corresponding power density and/or power output provided by the solid oxide fuel cell prior to delivery of the irradiated oxygen that is operated at a second operating temperature higher than the first operating temperature.

51. The method of claim 50, wherein the step of irradiating oxygen with light comprises irradiating oxygen with light having power density greater than about 10 mW/cm².

52. The method of claim 51, wherein the step of irradiating oxygen with light comprises irradiating oxygen with light having power density greater than about 40 mW/cm².

53. The method of claim 50, wherein the method comprises heating the solid oxide electrolyte layer to a temperature greater than about 400° C.

54. The method of claim 53, wherein the method comprises heating the solid oxide electrolyte layer to a temperature greater than about 600° C.

55. The method of claim 54, wherein the method comprises heating the solid oxide electrolyte layer to a temperature greater than about 800° C.

56. The method of claim 49, wherein the solid oxide electrolyte layer comprises a polycrystalline ceramic comprising one or more of stabilized zirconia, partially stabilized zirconia, stabilized hafnia, partially stabilized hafnia, mixtures of zirconia and hafnia, ceria with zirconia, bismuth with zirconia, gadolinium germanium, and mixtures thereof.

57. The method of claim 49, wherein the solid oxide electrolyte layer comprises a polycrystalline ceramic comprising one or more of yttria-doped bismuth oxide (YDB), gadolinia-doped ceria (GDC), and yttria stabilized zirconia (YSZ).

58. The method of claim 50, wherein the solid oxide electrolyte layer is less than about 100 nm thick.

59. The method of claim 50, wherein the solid oxide fuel cell comprises a cathode layer on the solid oxide electrolyte layer and the cathode layer is less than about 1000 nm thick.

60. The method of claim 50, wherein the first operating temperature is at least 100° C. less than the second operating temperature.

61. The method of claim 60, wherein the first operating temperature is at least 200° C. less than the second operating temperature.

62. The method of claim 61, wherein the first operating temperature is at least 300° C. less than the second operating temperature.

63. The method of claim 50 or 60, wherein the step of delivering the irradiated oxygen to the cathode side comprises irradiating the cathode side of the solid oxide fuel cell with light having one or more wavelengths in the range between about 100 nm to about 365.

64. The method of claim 63, wherein irradiating the cathode side of the solid oxide fuel cell with light comprises irradiating the oxide ion conducting layer with light having power density greater than about 10 mW/cm².

65. The method of claim 63, wherein irradiating the cathode side of the solid oxide fuel cell with light comprises irradiating the oxide ion conducting layer with solar radiation concentrated by greater than about a factor of 2.

66. A method for improving the operation of a solid oxide fuel cell having a solid oxide electrolyte layer less than about 1000 inn thick, comprising the steps of
irradiating oxygen with light having one or more wavelengths in the range between about 100 nm, to about 365 nm; and
delivering the irradiated oxygen to the cathode side of a solid oxide fuel cell having a solid oxide electrolyte layer less than about 1000 nm thick in an amount sufficient to increase one or more of the power density and power output provided by the solid oxide fuel cell as compared to the corresponding power density and/or power output provided by the solid oxide fuel cell prior to delivery of the irradiated oxygen.

67. The method of claim 66, wherein the step of irradiating oxygen with light comprises irradiating oxygen with light having power density greater than about 10 mW/cm².

68. The method of claim 67, wherein the step of irradiating oxygen with light comprises irradiating oxygen with light having power density greater than about 40 mW/cm².

69. The method of claim 66, wherein the method comprises heating the solid oxide electrolyte layer to a temperature greater than about 400° C.

70. The method of claim 69, wherein the method comprises heating the solid oxide electrolyte layer to a temperature greater than about 600° C.

71. The method of claim 70, wherein the method comprises heating the solid oxide electrolyte layer to a temperature greater than about 800° C.

72. The method of claim 66, wherein the solid oxide electrolyte layer comprises a polycrystalline ceramic comprising one or more of stabilized zirconia, partially stabilized zirconia, stabilized hafnia, partially stabilized hafnia, mixtures of zirconia and hafnia, ceria with zirconia, bismuth with zirconia, gadolinium, germanium, and mixtures thereof.

73. The method of claim 66, wherein the solid oxide electrolyte layer comprises a polycrystalline ceramic comprising one or more of yttria-doped bismuth oxide (YDB), gadolinia-doped ceria (GDC), and yttria-stabilized zirconia (YSZ).

74. The method of claim 66, wherein the solid oxide electrolyte layer is less than about 100 nm thick.

75. The method of claim 66, wherein the solid oxide fuel cell comprises a cathode layer on the solid oxide electrolyte layer and the cathode layer is less than about 1000 nm thick.

76. The method of claim 66, wherein the step of delivering the irradiated oxygen to the cathode side comprises irradiating the cathode side of the solid oxide fuel cell with light having one or more wavelengths in the range between about 100 nm to about 365 nm.

77. The method of claim 76, wherein irradiating the cathode side of the solid oxide fuel cell with light comprises irradiating the oxide ion conducting layer with light having power density greater than about 10 mW/cm².

78. The Method of claim 76, wherein irradiating the cathode side of the solid oxide fuel cell with light comprises irradiating the oxide ion conducting layer with solar radiation concentrated by greater than about a factor of 2.
